(19) United States
(12) Patent Application Publication
(10) Pub. No.: US 2009/0229523 A1
(43) Pub. Date: Sep. 17, 2009

(54) FILM DEPOSITING APPARATUS

(75) Inventor: Tatsuya FUJINAMI, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/403,948

(22) Filed: Mar. 13, 2009

(30) Foreign Application Priority Data
Mar. 14, 2008 (JP) 2008-065598

(51) Int. Cl. C23C 16/54

(52) U.S. Cl. 118/723 R

(57) ABSTRACT

A film depositing apparatus comprises: a chamber; a rotatable cylindrical drum that is provided within the chamber, and around which a substrate is wrapped in a specified surface region; a film depositing electrode spaced apart from and in a face-to-face relationship with a surface of the drum, and a feed gas supply section from which a feed gas for forming a film is supplied into a gap between the drum and the film depositing electrode; and a gas-flow regulating unit that regulates the feed gas as supplied into the gap between the drum and the film depositing electrode during film formation to be easier to flow in a direction in which the drum rotates than in a direction along which the axis of rotation of the drum extends.

The entire contents of a document cited in this specification are incorporated herein by reference.

### BACKGROUND OF THE INVENTION

The present invention relates to a film depositing apparatus for forming a film on a surface of an elongated substrate in vacuum by CVD and, more particularly, to a film depositing apparatus which, when forming a film continuously on the elongated substrate as it is transported, is capable of forming a film having high uniformity in thickness in the direction of width of the substrate perpendicular to its longitudinal direction.

While various types of apparatus are known to be capable of continuous film deposition on an elongated substrate (a web of substrate) in a vacuum-filled chamber by plasma-enhanced CVD, an exemplary system uses a drum electrically connected to the ground and an electrode positioned in a face-to-face relationship with the drum and connected to a radio-frequency power source.

In this type of film depositing apparatus, the substrate is wrapped around a specified area of the drum, which is then rotated to thereby transport the substrate in a longitudinal direction as it is in registry with a specified film depositing position, with a radio-frequency voltage being applied between the drum and the electrode to form an electric field while, at the same time, a feed gas for film deposition as well as argon gas and the like are introduced between the drum and the electrode, whereby a film is deposited on the surface of the substrate by plasma-enhanced CVD. This type of film depositing apparatus has already been proposed (see JP 2006-152416 A).

JP 2006-152416 A discloses an apparatus for plasma-enhanced CVD that comprises a reaction compartment, gas inlets through which reactive gases are introduced into the reaction compartment, an anode and a cathode electrode that are provided within the reaction compartment to generate plasma discharge between themselves, and a transport mechanism that transports a flexible substrate between the anode and the cathode electrode; the apparatus treats the flexible substrate by plasma-enhanced CVD.

The reaction compartment has four gas discharging units for discharging the gas from the inside (see FIG. 1 in JP 2006-152416 A) and each gas discharging unit is equipped with a vacuum pump such as a mechanical booster pump or a rotary pump.

The anode electrode has a curved, first discharge surface whereas the cathode electrode has a second discharge surface that is curved along the first discharge surface. The cathode electrode is provided with an electrode-to-electrode distance adjusting mechanism for moving it in a direction parallel to the diameter of the anode electrode, as well as a curvature adjusting mechanism for performing fine adjustment on the curvature of the second discharge surface in accordance with the distance between the anode and cathode electrodes.

### SUMMARY OF THE INVENTION

In the plasma-enhanced CVD apparatus disclosed in JP 2006-152416 A, the reaction compartment is equipped with four gas discharging units for discharging the gas from the inside; however, these units are not provided in symmetrical positions but are located eccentrically with respect to the space between the first discharge surface of the anode electrode and the second discharge surface of the cathode electrode. Thus, in JP 2006-152416 A, when reactive gases are supplied for film deposition, with the flexible substrate being provided between the first discharge surface of the anode electrode and the second discharge surface of the cathode electrode, these reactive gases are discharged in various directions including, for example, the direction of width of the flexible substrate. In this case, the reactive gases flow from the center of the flexible substrate toward either end, where they accumulate to form a film that is thicker at both ends of the flexible substrate to thereby yield an uneven thickness distribution in the direction of its width. Hence, the plasma-enhanced CVD apparatus disclosed in JP 2006-152416 A which does not take into account the direction in which the reactive gases are to be discharged, has the problem that it is incapable of producing films having a uniform thickness distribution.

An object, therefore, of the present invention is to solve the aforementioned problem of the prior art by providing a film depositing apparatus which, when forming a film continuously on an elongated substrate as it is transported, is capable of forming a film having high uniformity in thickness in the direction of width of the substrate perpendicular to its longitudinal direction.

A film depositing apparatus according to the present invention comprises: a transport means that transports an elongated substrate in a specified transport path; a chamber; an evacuating unit that creates a specified degree of vacuum within the chamber; a rotatable cylindrical drum that is provided within the chamber, that has an axis of rotation in a direction perpendicular to a transport direction of the substrate by the transport means, which is longer than a size of the substrate as measured in the direction perpendicular to the transport direction of the substrate, and around which the substrate transported by the transport means is wrapped in a specified surface region; a film depositing unit comprising a film depositing electrode spaced apart from and in a face-to-face relationship with a surface of the drum, a radio-frequency power source section for applying a radio-frequency voltage to the film depositing electrode, and a feed gas supply section from which a feed gas for forming a film is supplied into a gap between the drum and the film depositing electrode; and a gas-flow regulating means that regulates the feed gas as supplied into the gap between the drum and the film depositing electrode during film formation to be easier to flow in a direction in which the drum rotates than in a direction along which the axis of rotation of the drum extends.

### BRIEF DESCRIPTION OF THE DRAWINGS

FIG. 1 is a schematic diagram showing a film depositing apparatus according to a first embodiment of the present invention.

FIG. 2 is a schematic side view showing the structure of a film depositing electrode in a film depositing compartment of the film depositing apparatus shown in FIG. 1.

FIGS. 3A, 3B and 4 are a schematic perspective view, a schematic front sectional view and a schematic plan view showing the relative positions of a drum, the film depositing electrode and cover plates in the film depositing compartment shown in FIG. 1, respectively.

FIG. 5 is schematic front sectional view showing the relative positions of the drum, the film depositing electrode and the cover plates in a film depositing compartment of a film depositing apparatus according to a modification of the first embodiment.

FIGS. 6A and 6B are a schematic perspective view and a schematic front sectional view showing the relative positions of the drum, the film depositing electrode plate and end portion members in a film depositing apparatus according to a second embodiment, respectively.

FIG. 7 is a schematic front sectional view showing a film depositing compartment of a film depositing apparatus according to a third embodiment.

### DETAILED DESCRIPTION OF THE INVENTION

On the following pages, the film depositing apparatus of the present invention is described in detail with reference to the preferred embodiments shown in the accompanying drawings.

### First Embodiment

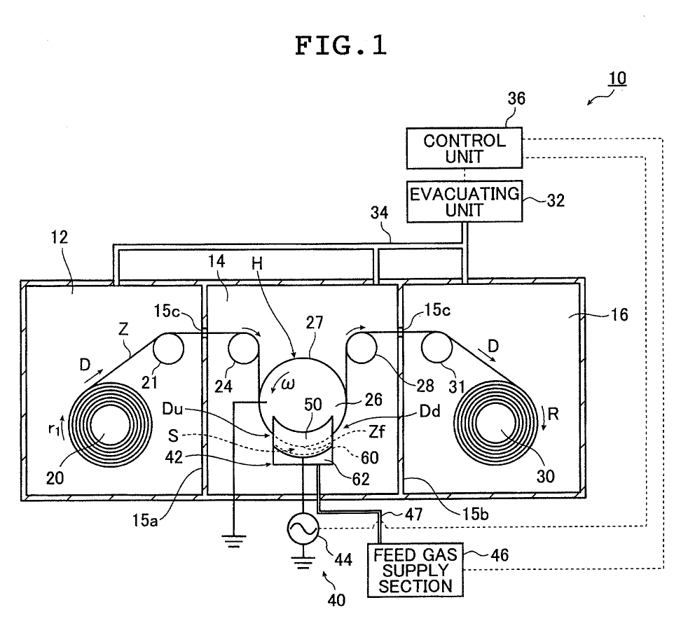

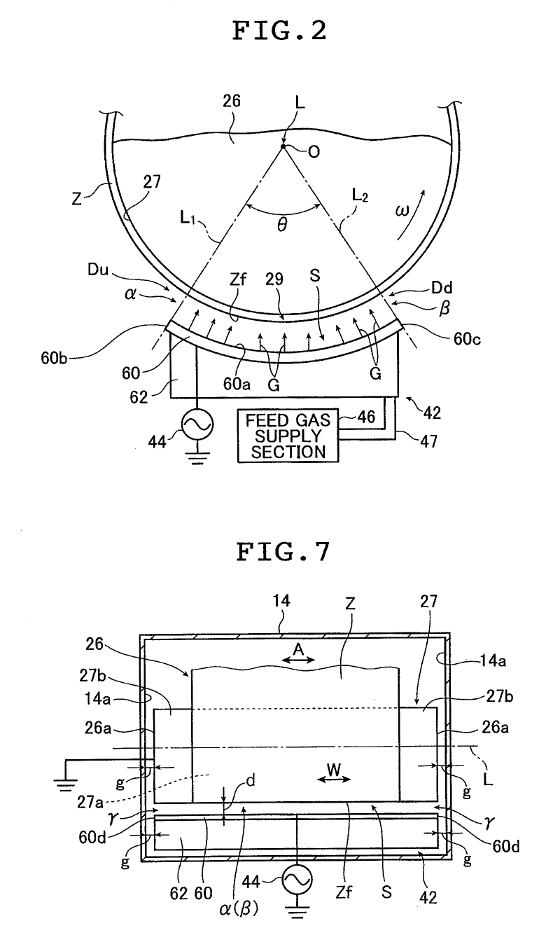

FIG. 1 is a schematic diagram showing a film depositing apparatus according to a first embodiment of the present invention. FIG. 2 is a schematic side view showing the structure of a film depositing electrode in a film depositing compartment of the film depositing apparatus shown in FIG. 1.

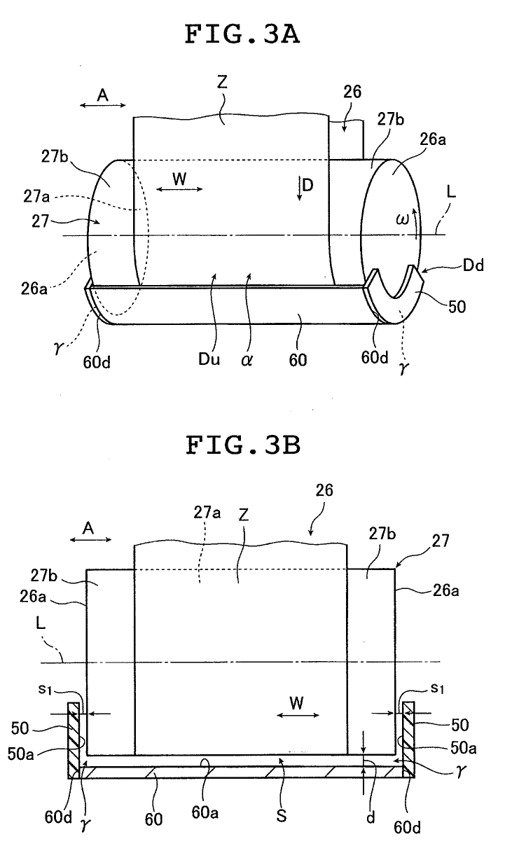

FIG. 3A is a schematic perspective view showing the relative positions of a drum, the film depositing electrode and cover plates in the film depositing compartment of the film depositing apparatus shown in FIG. 1. FIG. 3B is a schematic front sectional view showing the relative positions of the drum, the film depositing electrode and the cover plates in the film depositing compartment of the film depositing apparatus shown in FIG. 1.

The film depositing apparatus generally indicated by 10 in FIG. 1 is a roll-to-roll type machine that forms a film with a specified function on the surface Zf of a substrate Z or on the surface of an organic layer if it is formed on the surface Zf of the substrate Z; the film depositing apparatus 10 is typically employed to produce functional films such as an optical film or a gas barrier film.

The film depositing apparatus 10 is an apparatus for continuously depositing a film on an elongated substrate Z (a web of substrate Z); it comprises basically a feed compartment 12 for feeding the elongated substrate Z, a film depositing compartment (chamber) 14 for forming a film on the elongated substrate Z, a take-up compartment 16 for winding up the elongated substrate Z after the film has been formed on it, an evacuating unit 32, and a control unit 36. The control unit 36 controls the actions of the individual elements of the film depositing apparatus 10.

In the film depositing apparatus 10, the feed compartment 12 and the film depositing compartment 14 are partitioned by a wall 15a whereas the film depositing compartment 14 and the take-up compartment 16 are partitioned by a wall 15b; a slit of opening 15c through which the substrate Z can pass is formed in each of the walls 15a and 15b.

In the film depositing apparatus 10, each of the feed compartment 12, the film depositing compartment 14 and the take-up compartment 16 is connected to the evacuating unit 32 via a piping system 34. The evacuating unit 32 creates a specified degree of vacuum in the interiors of the feed compartment 12, the film depositing compartment 14, and the take-up compartment 16.

To evacuate the feed compartment 12, the film depositing compartment 14 and the take-up compartment 16 to maintain a specified degree of vacuum, the evacuating unit 32 has vacuum pumps such as a dry pump and a turbo-molecular pump. Each of the feed compartment 12, the film depositing compartment 14 and the take-up compartment 16 is equipped with a pressure sensor (not shown) for measuring the internal pressure.

Note that the ultimate degree of vacuum that should be created in the feed compartment 12, the film depositing compartment 14 and the take-up compartment 16 by the evacuating unit 32 is not particularly limited and an adequate degree of vacuum suffices to be maintained in accordance with such factors as the method of film deposition to be performed. The evacuating unit 32 is controlled by the control unit 36.

The feed compartment 12 is a site for feeding the elongated substrate Z, where a substrate roll 20 and a guide roller 21 are provided.

The substrate roll 20 is for delivering the elongated substrate Z continuously and it typically has the substrate Z wound around it.

The substrate roll 20 is typically connected to a motor (not shown) as a drive source. By means of this motor, the substrate roll 20 is rotated in a direction r in which the substrate Z is rewound; in the embodiment under consideration, the substrate roll 20 is rotated clockwise to deliver the substrate Z continuously in FIG. 1.

The guide roller 21 is for guiding the substrate Z into the film depositing compartment 14 in a specified transport path. The guide roller 21 is composed of a known guide roller.

In the film depositing apparatus 10 of the first embodiment, the guide roller 21 may be a drive roller or a follower roller. Alternatively, the guide roller 21 may be a roller that works as a tension roller that adjusts the tension that develops during the transport of the substrate Z.

In the film depositing apparatus of the present invention, the substrate Z is not particularly limited and all kinds of substrates can be employed as long as films can be formed by vapor-phase film deposition techniques. Usable as the substrate Z are various resin films such as a PET film, and various metal sheets such as an aluminum sheet.

The take-up compartment 16 is a site where the substrate Z with a film having been formed on the surface Zf in the film depositing compartment 14 is wound up; in this take-up compartment 16, there are provided a take-up roll 30 and a guide roller 31.

The take-up roll 30 is a device by which the substrate Z on which a film has been deposited is wound up in a roll.

The take-up roll 30 is typically connected to a motor (not shown) as a drive source. By means of this motor, the take-up roll 30 is rotated to wind up the substrate Z after the film deposition step.

By means of the motor, the take-up roll 30 is rotated in a direction R in which the substrate Z is wound up; in the first embodiment, the take-up roll 30 is rotated clockwise in FIG. 1, whereupon the substrate Z after the film deposition step is wound up continuously.

The guide roller 31 is similar to the aforementioned guide roller 21 in that the substrate Z being delivered from the film depositing compartment 14 is guided by this roller to the take-up roll 30 in a specified transport path. The guide roller 31 is composed of a known guide roller. Note that like the guide roller 21 in the feed compartment 12, the guide roller 31 may be a drive roller or a follower roller. Alternatively, the guide roller 31 may be a roller that works as a tension roller.

The film depositing compartment 14 functions as a vacuum chamber and it is a site where a film is continuously formed on the surface Zf of the substrate Z by a vapor-phase film deposition technique, typically by plasma-enhanced CVD, as the substrate Z is being transported.

The film depositing compartment 14 is typically constructed by using materials such as stainless steel that are commonly employed in a variety of vacuum chambers.

In the film depositing compartment 14, there are provided two guide rollers 24 and 28, as well as a drum 26 and a film depositing unit 40.

The guide rollers 24 and 28 are spaced apart parallel to each other in a face-to-face relationship; they are also provided in such a way that their longitudinal axes cross at right angles to a direction D in which the substrate Z is transported.

The guide roller 24 is a device by which the substrate Z delivered from the guide roller 21 provided in the feed compartment 12 is transported to the drum 26. The guide roller 24 is rotatable, typically having an axis of rotation in a direction perpendicular to the transport direction D of the substrate Z (this direction is hereinafter referred to as the axial direction), and its length in the axial direction is greater than the length in a width direction W perpendicular to the longitudinal direction of the substrate Z (the latter length is hereinafter referred to as the width of the substrate Z).

Note that the substrate roll 20 and the guide rollers 21 and 24 combine to constitute a first transport means in the present invention.

The guide roller 28 is a device by which the substrate Z wrapped around the drum 26 is transported to the guide roller 31 provided in the take-up compartment 16. The guide roller 28 is rotatable, typically having an axis of rotation in the axial direction, and its length in the axial direction is greater than the width of the substrate Z.

Note that the guide rollers 28 and 31 as well as the take-up roll 30 combine to constitute a second transport means in the present invention.

Except for the features just described above, the guide rollers 24 and 28 have the same structure as the guide roller 21 provided in the feed compartment 12, so they will not be described in detail.

The drum 26 is provided below the space H between the guide rollers 24 and 28. The drum 26 is so positioned that its longitudinal axis is parallel to those of the guide rollers 24 and 28. Also note that the drum 26 is electrically connected to the ground.

The drum 26 typically assumes a cylindrical shape and has a rotational axis L (see FIG. 3A). The drum 26 has end faces 26a that are perpendicular to the rotational axis L and which are in a face-to-face relationship with each other in the axial direction A along which the rotational axis L extends (this may be called the direction of the rotational axis). The drum 26 is capable of rotating in the direction of rotation ω about the rotational axis L. Also note that the length of the drum 26 in the axial direction A is greater than the width of the substrate Z. The drum 26, as it rotates with the substrate Z wrapped around its surface 27 (peripheral surface), transports the substrate Z in the transport direction D while it is kept in registry with a specified film depositing position.

It is assumed that the side to the direction of travel parallel to the direction of rotation ω of the drum 26, namely, the side to which the substrate Z is transported is the downstream side Dd, and the side opposite to this downstream side Dd is the upstream side Du.

For temperature adjustment, the drum 26 may be provided in its center with a heater (not shown) for heating the drum 26 and a temperature sensor (also not shown) for measuring the temperature of the drum 26. In this case, the heater and the temperature sensor are connected to the control unit 36 which adjusts the temperature of the drum 26 such that it is held at a specified temperature.

As shown in FIG. 1, the film depositing unit 40 is provided below the drum 26 which, with the substrate Z being wrapped around it, rotates so that a film is formed on the surface Zf of the substrate Z as it is transported in the transport direction D.

The film depositing unit 40 is a device to form a film, typically by capacitively coupled plasma enhanced CVD (CCP-CVD). The film depositing unit 40 has a film depositing electrode 42, a radio-frequency power source 44, and a feed gas supply section 46. The control unit 36 controls the radio-frequency power source 44 and the feed gas supply section 46 in the film depositing unit 40.

In the film depositing unit 40, the film depositing electrode 42 is provided in the lower part of the film depositing compartment 14 such that it is spaced by a specified gap S from the surface 27 of the drum 26. The film depositing electrode 42 is fitted with cover plates (first cover members) 50 in such a way as to cover the end portions γ in the axial direction A of the gap S, that is, the direction of width W of the substrate Z (see FIGS. 3A and 3B).

As shown in FIG. 2, the film depositing electrode 42 has a film depositing electrode plate 60 and a holder 62 that holds the film depositing electrode plate 60.

The film depositing electrode plate 60 may be formed by bending a rectangular member in a curved shape, typically with the same curvature as the surface 27 of the drum 26.

The film depositing electrode plate 60 is disposed along the direction of rotation ω as if to follow the surface 27 of the drum 26, with its length being parallel to the rotational axis L of the drum 26 and with its surface 60a being oriented to the surface 27 of the drum 26.

In the first embodiment, the film depositing electrode plate 60 is typically disposed in such a way that it aligns with a circle concentric with the surface 27 of the drum 26. The film depositing electrode plate 60 is set at a specified distance which, in any of its regions, is equal to the distance between the surface 60a of the film depositing electrode plate 60 and the surface 27 of the drum 26 as measured on a line that is perpendicular to the surface 60a and which passes through the center of rotation O of the drum 26.

In the first embodiment, the film depositing electrode plate 60 is curved to follow the surface 27 of the drum 26 but this is not the sole case of the present invention and a rectangular member may be bended in a similar shape; alternatively, a number of flat rectangular electrode platelets may be arranged along the direction of rotation ω so as to follow the surface 27 of the drum 26. In this alternative case, electrical conduction is established between the individual electrode platelets, which are arranged in such a way that each electrode platelet is set at a specified distance which is equal to the distance between the surface of each electrode platelet and the surface 27 of the drum 26 as measured on a line that is perpendicular to that surface and which passes through the center of rotation O of the drum 26.

As shown in FIG. 1, the film depositing electrode 42 (film depositing electrode plate 60) is connected to the radio-frequency power source 44, which applies a radio-frequency voltage to the film depositing electrode plate 60 in the film depositing electrode 42. The radio-frequency power source 44 is capable of varying the radio-frequency power (RF power) to be applied. Note that the film depositing electrode 42 and the radio-frequency power source 44 may optionally be connected to each other via a matching box in order to attain impedance matching.

The film depositing electrode 42 is of a type that is generally called “a shower head electrode” and the film depositing electrode plate 60 has a plurality of through-holes (not shown) formed at equal spacings in its surface 60a. By means of this film depositing electrode 42, the feed gas G is supplied uniformly into the gap S.

The holder 62 is for holding the film depositing electrode plate 60 and, with its interior being hollow (not shown), is connected to the feed gas supply section 46 via a pipe 47. The hollow portion of the holder 62 communicates with the plurality of through-holes formed in the surface 60a of the film depositing electrode plate 60.

As will be described later, the feed gas G supplied from the feed gas supply section 46 flows through the pipe 47, the hollow portion of the holder 62 and the plurality of through-holes in the film depositing electrode plate 60 to be released from the surface 60a of the film depositing electrode plate 60 so that it is supplied uniformly into the gap S.

To adjust the temperature of the film depositing electrode plate 60, the holder 62 may be equipped with a heater (not shown) for heating the film depositing electrode plate 60 and a temperature sensor (also not shown) for measuring the film depositing electrode plate 60. In this case, the heater and the temperature sensor are connected to the control unit 36 which adjusts the temperature of the film depositing electrode plate 60 such that it is held at a specified temperature.

As just described above, the drum 26 and the film depositing electrode plate 60 are each equipped with the heater (not shown) and the temperature sensor (also not shown); this design ensures that the drum 26 has the same temperature as the film depositing electrode plate 60.

The feed gas supply section 46 supplies the film-forming feed gas G into the gap S through the plurality of through-holes formed in the surface 60a of the film depositing electrode plate 60 in the film depositing electrode 42. The gap S between the surface 27 of the drum 26 and the film depositing electrode 42 serves as a space where plasma is to be generated, hence, as a film deposition space.

In the embodiment under consideration, if a SiO₂ film is to be formed, the feed gas G is a TEOS gas, with oxygen gas being used as an active species gas. If a silicon nitride film is to be formed, SiH₄ gas, NH₃ gas and N₂ gas (dilution gas) are used. In the first embodiment, even a feed gas containing an active species gas and a dilution gas is simply referred to as a feed gas.

The feed gas supply section 46 may be chosen from a variety of gas introducing means that are employed in the CVD apparatus.

Also note that the feed gas supply section 46 may supply into the gap S not only the feed gas G but also an inert gas such as argon or nitrogen gas, an active species gas such as oxygen gas, and various other gases that are used in CVD. In this case of introducing more than one species of gas, the respective gases may be mixed together in the same pipe and the mixture be passed through the plurality of holes in the film depositing electrode 42 to be supplied into the gap S; alternatively, the respective gases may be supplied through different pipes and passed through the plurality of holes in the film depositing electrode 42 to be supplied into the gap S.

The kinds of the feed gas, the inert gas and the active species gas, as well as the amounts in which they are introduced may be chosen and set as appropriate for various considerations including the kind of the film to be formed and the desired film deposition rate.

Note that the radio-frequency power source 44 may be of any known type that is employed in film deposition by plasma-enhanced CVD. The maximum power output and other characteristics of the radio-frequency power source 44 are not particularly limited and may be chosen and set as appropriate for various considerations including the kind of the film to be formed and the desired film deposition rate.

The film depositing electrode 42 is in no way limited to such a configuration that a rectangular member is bent in a curved shape and various other electrode configurations may be adopted as long as they are capable of film deposition by CVD; to give one example, it may consist of electrode segments that are arranged in the axial direction of the drum 26.

In the first embodiment, the film depositing electrode 42 is of such a configuration that through-holes are formed in the surface 60a of the film depositing electrode plate 60. However, this is not the sole embodiment of the present invention and, as long as the feed gas G can be uniformly supplied to the gap S serving as the film deposition space, slits of opening may be formed in the bent portions of the film depositing electrode plate 60 such that the feed gas G is released through the slits.

Also suppose the following on the assumption that the film depositing electrode plate 60 has two end portions 60b and 60c as shown in FIG. 2: the line by which the end portion 60b on the upstream side Du in the direction of rotation ω of the drum 26 is connected to the center of rotation O of the drum 26 is written as the first line L₁; the line by which the end portion 60c on the downstream side Dd in the direction of rotation ω of the drum 26 is connected to the center of rotation O of the drum 26 is written as the second line L₂; the angle formed between the first line L₁ and the second line L₂ is written as θ. Since a film is deposited on the surface Zf of the substrate Z over the range of angle θ, the range of angle θ is the film deposition zone 29.

Note that in FIGS. 3A and 3B, only the film depositing electrode plate 60 is shown as part of the film depositing electrode 42 and the other structural parts are not shown.

As shown in FIGS. 3A and 3B, cover plates 50 do not cover all parts of the gap S defined by the drum 26 and the film depositing electrode plate 60 but they cover the two end portions γ of the gap S in the axial direction A of the drum 26 (i.e., the longitudinal direction of the drum 26). As shown in FIGS. 3A and 3B, the cover plates 50 are provided at the respective end portions 60d of the film depositing electrode plate 60 in the axial direction A.

The cover plates 50 are each made of a member in plate form having a circular arc shape with a radius corresponding to the curvature of the curved film depositing electrode plate 60; they cover the end portions γ of the gap S and partially overlap the end faces 26a of the drum 26. An end face 50a of the cover plate 50 which is in a face-to-face relationship with the corresponding end face 26a of the drum 26 is spaced by a specified distance s₁ from that end face 26a of the drum 26. The distance s₁ is shorter than the distance d in the gap S. It should be noted here that the cover plates 50 are composed of an insulator such as ceramics including alumina. In the first embodiment, the gap S is left open at the end portions α and β in the direction of rotation ω and communicates with the interior of the film depositing compartment 14.

In the first embodiment, the end portions γ of the gap S are closed with the cover plates 50 and the distance s₁ between each cover plate 50 and the corresponding end face 26a of the drum 26 is made shorter than the distance d in the gap S whereas the gap S is left open at the end portions α and β; as a result, a fluid flowing through the gap S in the axial direction A (longitudinal direction) of the drum 26 will experience a greater resistance than when it flows through the end portions α and β of the gap S in the direction of rotation ω of the drum 26 (the transport direction D of the substrate Z) where the gap S is open and presents no resistance. As a result, the fluid flows less smoothly in the axial direction A of the drum 26 than in the longitudinal direction of the substrate Z. Thus, the fluid flows through the gap S more efficiently in the direction of rotation ω of the drum 26 than in the axial direction A (longitudinal direction) of the drum 26.

To put this in terms of conductance which is an index for the ease with which the fluid flows, the first conductance in the direction of rotation ω of the drum 26 is greater than the second conductance in the longitudinal direction of the drum 26 (the direction of width W of the substrate Z). Note that the greater the conductance, the more easily the fluid will flow.

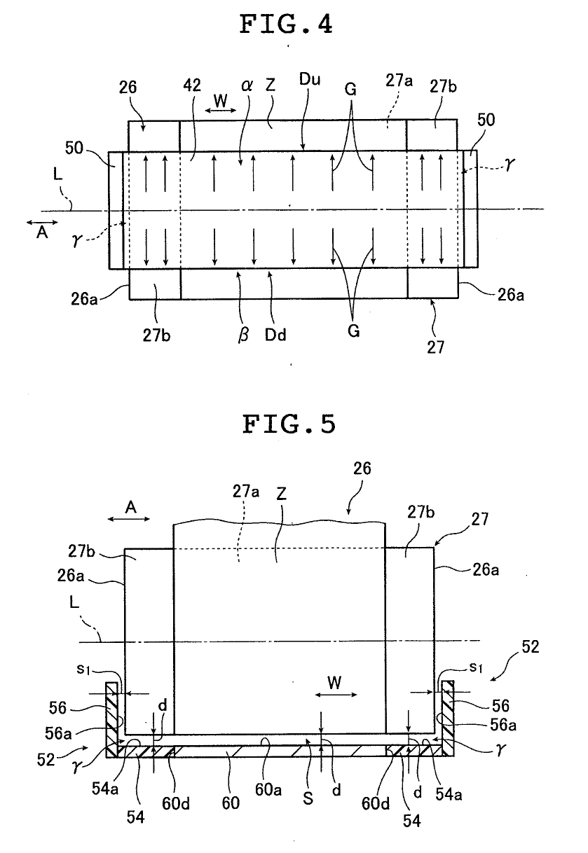

Suppose here that during film deposition in the first embodiment, the feed gas G is supplied into the gap S from the feed gas supply section 46, with a specified degree of vacuum being created within the film depositing compartment 14; then, as shown in FIG. 4, the pressure difference between the gap S and the film depositing compartment 14 causes the feed gas G to flow through the gap S preferentially along the surface 27 of the drum 26 in the direction of its rotation ω whereas the feed gas G is suppressed from flowing in the axial direction A of the drum 26. As a result, the feed gas G is preferentially discharged through the end portions α and β of the gap S into the film depositing compartment 14 held at the specified degree of vacuum whereas the feed gas G is inhibited from flowing in the axial direction A of the drum 26 (the direction of width W of the substrate Z). This suppresses any disturbances in the flow of the feed gas G in the direction of width W of the substrate Z and the feed gas G will be discharged uniformly in the direction of width W of the substrate Z.

In addition, the first embodiment merely involves the need to position the cover plates 50 in such a way that they close the end portions γ of the gap S and that the distance s₁ to either end face 26a of the drum 26 is shorter than the distance d of the gap S; hence, it is at low cost that the feed gas G in the gap S can be discharged uniformly in the direction of width W of the substrate Z while the feed gas G can be supplied uniformly into the gap S in the direction of width W.

In the first embodiment, the cover plates 50 are provided at the end portions 60d of the film depositing electrode plate 60 in its axial direction A; it should, however, be noted that the structure of the cover plates is by no means limited to this particular case and each of them may be replaced by a cover member 52 (see FIG. 5) which comprises a first part 54 and a second part 56. The cover member 52 has an L-shaped cross section and is disposed in such a way that it surrounds part of the surface 27 of the drum 26 as well as part of each end face 26a of the drum 26.

If the cover member 52 is to be provided, the length of the film depositing electrode plate 60 in its axial direction A is made generally the same as the width of the substrate Z and positioned in a face-to-face relationship with the region 27a of the drum 26 around which the substrate Z is wrapped.

The first part 54 of the cover member 52 is a member in plate form that is curved with the same curvature as the film depositing electrode plate 60 and which is positioned in a face-to-face relationship with the region 27b of the drum 26 around which the substrate Z is not wrapped. The first part 54 of the cover member 52 is connected to the corresponding end portion 60d of the film depositing electrode plate 60 such that it is made integral with the film depositing electrode 60. The distance between the surface 54a of the first part 54 and the surface 27 of the drum 26 is the same as the distance d between the surface 60a of the film depositing electrode plate 60 and the surface 27 of the drum 26.

The second part 56 of the cover member 52 is connected to the first part 54 but spaced from the corresponding end face 26a of the drum 26 in its axial direction A. The second part 56 is constructed in the same way as the cover plate 50 in the first embodiment and is made of a member in plate form having a circular arc shape with a radius corresponding to the curvature of the film depositing electrode plate 60.

The second part 56 is such that the distance between the end face 26a of the drum 26 and the corresponding face 56a of the second part 56 is s₁ and shorter than the distance d in the gap S, as in the case of the cover plate 50 in the first embodiment. Note further that the first part 54 and the second part 56 of the cover member 52 are also made of an insulator such as ceramics including alumina.

The above-described modifications of the first embodiment are also capable of attaining the same effects as the first embodiment but, in addition, since the film depositing electrode plate 60 does not extend as far as the region 27b of the drum 26 around which the substrate Z is not wrapped, the reaction product can be suppressed from accumulating in that region 27b.

We next describe how the film depositing apparatus 10 according to the first embodiment works.

In the specified path starting from the feed compartment 12 and passing through the film depositing compartment 14 to reach the take-up compartment 16, the elongated substrate Z is transported through the film depositing apparatus 10 from the feed compartment 12 down to the take-up compartment 16 while a film is formed on the substrate Z in the film depositing compartment 14.

In the film depositing apparatus 10, the elongated substrate Z that has been wound around the substrate roll 20 is unwound and transported into the film depositing compartment 14 via the guide roller 21. In the film depositing compartment 14, the substrate Z passes over the guide roller 24, the drum 26 and the guide roller 28 to be transported into the take-up compartment 16. In the take-up compartment 16, the elongated substrate Z passes over the guide roller 31 to be wound up by the take-up roll 30. After passing the elongated substrate Z through this transport path, a specified degree of vacuum is maintained in the interiors of the feed compartment 12, the film depositing compartment 14 and the take-up compartment 16 by means of the evacuating unit 32; then, in the film depositing unit 40, a radio-frequency voltage is applied from the radio-frequency power source 44 to the film depositing electrode 42 while, at the same time, the feed gas G to form a film is uniformly supplied from the feed gas supply section 46 through the pipe 47 and the holder 62 so that it is released into the gap S through the plurality of through-holes formed in the surface 60a of the film depositing electrode plate 60.

When electromagnetic waves are radiated around the film depositing electrode 42, a plasma localized in the neighborhood of the film depositing electrode 42 is generated in the gap S (film deposition space), whereupon the feed gas is excited and dissociated to yield a reaction product that serves to form a film. This reaction product accumulates to form a film of specified thickness on the surface Zf of the substrate Z within the range of the film depositing electrode 42, namely, in the film deposition zone 29 defined by the range of angle θ about the center of rotation O of the drum 26.

On this occasion, in the gap S between the drum 26 and the film depositing electrode 42 (the film depositing electrode plate 60), the pressure difference between the gap S and the film depositing compartment 14 causes the feed gas G to flow preferentially along the surface 27 of the drum 26 in the direction of its rotation ω (see FIG. 4) whereas the feed gas G is inhibited from flowing in the axial direction A of the drum 26. As a result, the feed gas G in the gap S is discharged uniformly in the direction of width W of the substrate Z while the feed gas G is supplied uniformly into the gap S in the direction of width W. Consequently, the reaction product formed by the feed gas G is supplied uniformly in the direction of width W of the substrate Z so that it accumulates on the surface Zf of the substrate Z uniformly in the direction of width W of the substrate Z. As a result, a uniform film having a small thickness distribution in the direction of width W is formed in a specified thickness.

Then, the substrate roll 20 around which the elongated substrate Z has been wound is rotated clockwise incrementally by means of the motor, whereupon the elongated substrate Z is delivered continuously and with the substrate Z being held on the drum 26 in the position where the plasma is being generated, the drum 26 is rotated at a specified speed to ensure that the film depositing unit 40 allows a layer to be formed continuously in a specified thickness on the surface Zf of the elongated substrate Z, particularly in such a way that it is uniform with a small thickness distribution in the direction of width W of the substrate Z. The substrate Z having the specified layer formed on its surface Zf passes over the guide rollers 28 and 31 so that the functional film, or the elongated substrate Z with the deposited layer, is wound up by the take-up roll 30.

Described above is the way in which the elongated substrate Z having the layer formed continuously in a specified thickness on the surface Zf, particularly in such a way that it is uniform with a small thickness distribution in the direction of width W of the substrate Z, namely, the functional film, can be produced by the film depositing apparatus 10 according to the first embodiment. The function of the functional film produced depends on the properties or the type of the layer formed on the substrate Z.

### Second Embodiment

We next describe a second embodiment of the present invention.

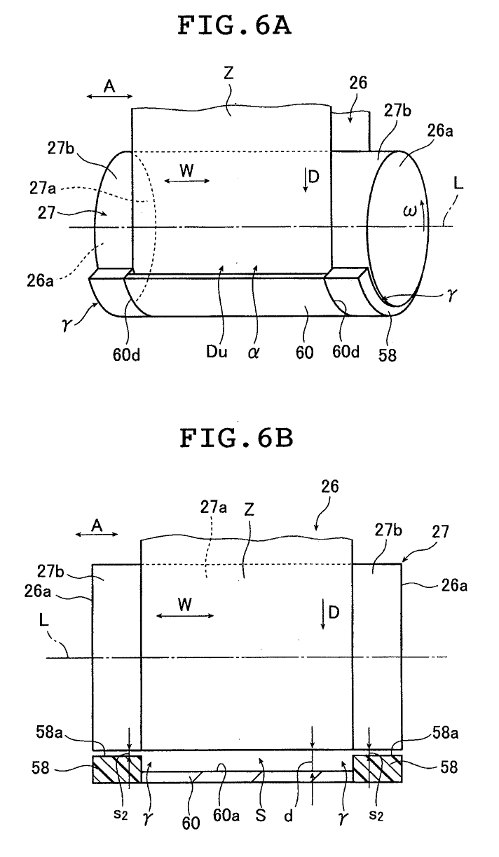

FIG. 6A is a schematic perspective view showing the relative positions of the drum, the film depositing electrode plate and end portion members in the film depositing apparatus according to the second embodiment of the present invention.

FIG. 6B is a schematic front sectional view showing the relative positions of the drum, the film depositing electrode plate and the end portion members in the film depositing apparatus according to the second embodiment of the present invention.

In the following description of the second embodiment, those structural elements which are identical to those of the film depositing apparatus according to the first embodiment which is shown in FIGS. 1 to 4 and those which are identical to the elements of the modification of the first embodiment which is shown in FIG. 5 are identified by like numerals or symbols and will not be described in detail.

Also note that in FIGS. 6A and 6B, only the drum, film depositing electrode plate and end portion members are illustrated and the illustration of the other elements is omitted. Those structural elements which are not illustrated in FIGS. 6A and 6B are identical to their counterparts in the film depositing apparatus according to the first embodiment.

The film depositing apparatus according to the second embodiment only differs from the film depositing apparatus 10 according to the first embodiment (see FIG. 1) in that the dimension of the film depositing electrode plate 60 in the longitudinal direction is shorter and that the end portion members (second cover members) 58 are provided in place of the cover plates 50; the other structural elements are identical to their counterparts in the film depositing apparatus 10 according to the first embodiment and will not be described in detail.

In the second embodiment, the length of the film depositing electrode plate 60 in the axial direction A (longitudinal direction) is generally the same as the length of the region 27a of the drum 26 around which the substrate Z is wrapped and it is positioned in a face-to-face relationship with this region 27a. A gap S is defined between the film depositing electrode plate 60 and the drum 26 to serve as a film deposition space; that part of the gap S which is in the neighborhood of each end portion 60a of the film depositing electrode plate 60 is an end portion γ in the axial direction A (longitudinal direction) of the drum 26.

Each of the end portion members 58 is in a face-to-face relationship with the region 27b of the drum 26 around which the substrate Z is not wrapped and it is provided in such a way that it substantially closes the corresponding end portion γ of the gap S and that it is integral with the corresponding end portion 60d of the film depositing electrode plate 60. The distance between the face 58a of each end portion member 58 that is in a face-to-face relationship with the drum 26 and the surface 27 of the region 27b of the drum 26 is s₂. The distance s₂ is shorter than the distance d between the drum 26 and the film depositing electrode 42. In other words, each of the end portion members 58 is positioned in such a way that the gap between its face 58a and the surface 27 of the drum 26 is narrower than the gap S between the drum 26 and the film depositing electrode 42.

The end portion members 58 are typically made of an insulator such as ceramics including alumina.

In the second embodiment, either end portion γ of the gap S (film deposition space) communicates with a narrower gap. Thus, when a fluid flowing through the gap S wants to go to the outside through the end portion γ, the end portion member 58 presents resistance to the passage of the fluid by constricting the gap S. As a result, the fluid will find it more difficult to flow through either end portion γ of the gap S in the axial direction A of the drum 26 than when it flows through the end portions α and β of the gap S where the gap S is open to the interior of the film depositing compartment 14. In other words, the feed gas G flows through the gap S more efficiently in the direction of rotation ω of the drum 26 than in its axial direction A. In the second as well as the first embodiment, the gap S (film deposition space) is such that the first conductance in the direction of rotation ω of the drum 26 is greater than the second conductance in the longitudinal direction of the drum 26 (the direction of width W of the substrate Z).

Thus, in the second as well as the first embodiment, the pressure difference between the gap S into which the feed gas G has been supplied for film deposition and the film depositing compartment 14 causes the feed gas G to flow through the gap S preferentially along the surface 27 of the drum 26 in the direction of its rotation ω whereas the feed gas G is suppressed from flowing through in the axial direction A of the gap S, to thereby yield the same effect as in the first embodiment.

What should also be mentioned about the second embodiment is that each of the end portion members 58 is provided n a face-to-face relationship with the region 27b of the drum 26 around which the substrate Z is not wrapped and the film depositing electrode plate 60 does not extend as far as this region 27b; hence, the reaction product is suppressed from accumulating in the region 27b of the drum 26 around which the substrate Z is not wrapped.

### Third Embodiment

We next describe a third embodiment of the present invention.

FIG. 7 is a schematic front sectional view showing the film depositing compartment of a film depositing apparatus according to the third embodiment of the present invention.

Note that in FIG. 7, the system configuration is illustrated in a simplified form and that only the drum, film depositing electrode plate and the radio-frequency power source are illustrated, with the illustration of the other elements being omitted. Those structural elements which are not illustrated in FIG. 7 are identical to their counterparts in the film depositing apparatus according to the first embodiment.

Also note that in the following description of the third embodiment, those structural elements which are identical to those of the film depositing apparatus according to the first embodiment which is shown in FIGS. 1 to 4 and those which are identical to the elements of the modification of the first embodiment which is shown in FIG. 5 are identified by like numerals or symbols and will not be described in detail.

The film depositing apparatus according to the third embodiment differs from the film depositing apparatus 10 according to the first embodiment (see FIG. 1) in that there are provided no cover plates 50 and they are also different in the size of the film depositing compartment 14; the other structural elements are identical to their counterparts in the film depositing apparatus 10 according to the first embodiment and will not be described in detail.

In the third embodiment, the length of the film depositing electrode plate 60 in the axial direction A is generally the same as the length of the drum 26 and each end face 26a of the drum 26 is flush with the corresponding end portion 60d of the film depositing electrode plate 60. A gap S is defined between the film depositing electrode plate 60 and the drum 26 to serve as a film deposition space. The distance in the gap S is d.

The film depositing compartment 14 according to the third embodiment is such that its inner surface 14a in a face-to-face relationship with the corresponding end face 26a of the drum 26 is spaced from the end face 26a of the drum 26 by a distance of g. The distance g between the end face 26a of the drum 26 and the inner surface 14a of the film depositing compartment 14 is shorter than the distance d in the gap S between the film depositing electrode 42 (the film depositing electrode plate 60) and the drum 26. In other words, the gap between the end face 26a of the drum 26 and the inner surface 14a of the film depositing compartment 14 is narrower than the gap S between the film depositing electrode 42 (the film depositing electrode plate 60) and the drum 26. Note that the end portions α and β of the gap S are open to the interior of the film depositing compartment 14.

In the third embodiment, the distance g between either end face 26a of the drum 26 and the inner surface 14a of the film depositing compartment 14 is made shorter than the distance d of the gap S between the film depositing electrode 42 (the film depositing electrode plate 60) and the drum 26. Thus, when a fluid flowing through the gap S wants to leave it through the end portion γ, the small distance g between either end face 26a of the drum 26 and the inner surface 14a of the film depositing compartment 14 poses a resistance to the passage of the fluid. As a result, the fluid will find it more difficult to flow through either end portion γ of the gap S in the axial direction A of the drum 26 than when it flows through the end portions α and β of the gap S where the gap S is open to the interior of the film depositing compartment 14. In other words, the feed gas G flows through the gap S more efficiently in the direction of rotation ω of the drum 26 than in its axial direction A. In the third as well as the first embodiment, the gap S (film deposition space) is such that the first conductance in the direction of rotation ω of the drum 26 is greater than the conductance of the flow through either end portion γ of the gap S in the axial direction A of the drum 26 into the film depositing compartment 14.

Thus, in the third as well as the first embodiment, the fluid can be caused to flow more smoothly in the direction of rotation ω (circumferential direction) of the drum 26 than in its axial direction A. Hence, as in the first embodiment, the pressure difference between the gap S into which the feed gas G has been supplied for film deposition and the film depositing compartment 14 causes the feed gas G to flow through the gap S preferentially along the surface 27 of the drum 26 in the direction of its rotation ω whereas the feed gas G is suppressed from flowing through in the axial direction A of the gap S, to thereby yield the same effect as in the first embodiment.

A further advantage of the third embodiment is that no extra structural members are required to control the direction in which the fluid can flow through the gap S more efficiently than in other directions and that therefore the production cost can be reduced.

In each of the foregoing embodiments of the present invention, the layer to be deposited is not particularly limited and as long as the CVD process is applicable, layers having the required functions that depend on the functional films to be produced can appropriately be formed. The thickness of the layer to be deposited is not particularly limited, either, and the required thickness may be determined as appropriate for the performance required by the functional film to be produced.

It should also be noted that the number of layers to be deposited is not limited to one but may be two or more. If a multi-layer film is to be formed, the individual layers may be the same or different from each other.

In each of the foregoing embodiments of the present invention, if a gas barrier film (water vapor barrier film) is to be produced as the functional film, the layer to be deposited on the substrate is an inorganic film such as a silicon nitride film, an aluminum oxide film, or a silicon oxide film.

If protective films for a variety of devices or apparatuses including display devices such as organic EL displays and liquid-crystal displays are to be produced as the functional film, the layer to be deposited on the substrate is an inorganic film such as a silicon oxide film.

Further in addition, if the functional film produced is any of an anti-light reflective film, a light reflective film, and various other optical films for use in filters, the layer to be deposited on the substrate is a film having the desired optical characteristics or a film comprising materials that exhibit the desired optical characteristics.

The functional film thus produced by the film depositing apparatus according to any one of the foregoing embodiments of the present invention is characterized in that the layer formed on the substrate has superior uniformity in thickness and, hence, uniform thickness, particularly in the direction of width of the substrate, so the functional film, if it is a gas barrier film, features good enough gas barrier property.

While the film depositing apparatus of the present invention has been described above in detail, the present invention is by no means limited to the foregoing embodiments and it should be understood that various improvements and modifications are possible without departing from the scope and spirit of the present invention.

What is claimed is:

1. A film depositing apparatus comprising:
a transport means that transports an elongated substrate in a specified transport path;
a chamber;
an evacuating unit that creates a specified degree of vacuum within the chamber;
a rotatable cylindrical drum that is provided within the chamber, that has an axis of rotation in a direction perpendicular to a transport direction of the substrate by the transport means, which is longer than a size of the substrate as measured in the direction perpendicular to the transport direction of the substrate, and around which the substrate transported by the transport means is wrapped in a specified surface region;
a film depositing unit comprising a film depositing electrode spaced apart from and in a face-to-face relationship with a surface of the drum, a radio-frequency power source section for applying a radio-frequency voltage to the film depositing electrode, and a feed gas supply section from which a feed gas for forming a film is supplied into a gap between the drum and the film depositing electrode; and
a gas-flow regulating means that regulates the feed gas as supplied into the gap between the drum and the film depositing electrode during film formation to be easier to flow in a direction in which the drum rotates than in a direction along which the axis of rotation of the drum extends.

2. The film depositing apparatus according to claim 1, wherein the gas-flow regulating means includes a first cover member that covers each of end portions of the gap between the drum and the film depositing electrode in the direction along which the axis of rotation of the drum extends.

3. The film depositing apparatus according to claim 1, wherein the gas-flow regulating means includes:
first members each of which is in a face-to-face relationship with the surface of the drum in a region around the substrate is not wrapped and which is provided integral with the film depositing electrode; and
second members that are connected to the first members and which cover the end portions of the gap in the direction along which the axis of rotation of the drum extends.

4. The film depositing apparatus according to claim 1, wherein the gas-flow regulating means includes second cover members each of which is in a face-to-face relationship with the surface of the drum in a region around which the substrate is not wrapped and is provided integral with the film depositing electrode, the second cover members being provided at a smaller spacing from the surface of the drum than the gap between the drum and the film depositing electrode.

5. The film depositing apparatus according to claim 1, wherein the gas-flow regulating means includes inner surfaces of the chamber facing to corresponding end faces of the drum with gaps which are narrower than the gap between the drum and the film depositing electrode.

6. The film depositing apparatus according to claim 1, wherein the film depositing electrode is a shower head electrode.
